(19) United States
(12) Patent Application Publication
(10) Pub. No.: US 2006/0273323 A1
(43) Pub. Date: Dec. 7, 2006

(54) Semiconductor device having SiC substrate and method for manufacturing the same

(75) Inventors: Takeo Yamamoto, Konan-city (JP); Malhan Rajesh Kumar, Nagoya-city (JP); Yuuichi Takeuchi, Obu-city (JP); Konstantin Vassilevski, Wallsend (GB); Nicholas Wright, Newcastle (GB)

Correspondence Address: POSZ LAW GROUP, PLC, 12040 SOUTH LAKES DRIVE, SUITE 101, RESTON, VA, 20191, US

(73) Assignees: DENSO CORPORATION, Kariya-city (JP); The University of Newcastle upon Tyne, Newcastle upon Tyne (GB)

(21) Appl. No.: 11/448,138

(22) Filed: Jun. 7, 2006

(30) Foreign Application Priority Data
Jun. 7, 2005 (JP) 2005-167401

(51) Int. Cl. H01L 31/0312

(52) U.S. Cl. 257/77

(57) ABSTRACT

A semiconductor device includes: a SiC substrate; a silicide layer disposed on the SiC substrate; and a carbide layer disposed on the silicide layer. The silicide layer includes a first metal, and the carbide layer includes a second metal. The first metal is Ni or Ni alloy, and the second metal is Ti, Ta or W. The device provides excellent ohmic contact and high quality surface metallization construction.

### CROSS REFERENCE TO RELATED APPLICATION

This application is based on Japanese Patent Application No. 2005-167401 filed on Jun. 7, 2005, the disclosure of which is incorporated herein by reference.

### FIELD OF THE INVENTION

The present invention relates to a semiconductor device having a SiC substrate and a method for manufacturing the same.

### BACKGROUND OF THE INVENTION

A semiconductor device having a SiC substrate is disclosed in, for example, Japanese Patent Application Publication No. 2003-243323. Specifically, an electrode construction of the device and a method for manufacturing the device are disclosed.

FIGS. 7A to 7D shows a method for manufacturing a semiconductor device having a SiC substrate according to a comparison of an embodiment of the present invention. Specifically, the method shown in FIGS. 7A to 7D is a surface metallization method, which is suitably used for forming an electrode. A metallization layer is formed on a backside of the SiC substrate 1 when a semiconductor device 9 is mounted on a base member such as a heat sink and a lead frame.

As shown in FIG. 7A, firstly, a nickel (i.e., Ni) film 2 for contacting other parts is formed on the surface of the SiC substrate 1. Then, the SiC substrate 1 with the Ni film 2 is heated at a predetermined high temperature so that the Ni film 2 provides an ohmic contact characteristic. This high temperature treatment provides an intermediate product layer 3. The intermediate product layer 3 is formed on the surface of a reaction layer 2a. The reaction layer 2a is formed from reaction between the Ni film 2 and the SiC substrate 1. The intermediate product layer 3 is formed from a particle such as a Ni carbide particle and a carbon (i.e., C) particle. When the intermediate product layer 3 is disposed on the surface of the reaction layer 2a, bonding strength of a metallic film 4 is reduced, and therefore, the metallic film 4 may be peeled off from the reaction layer 2a. Here, the metallic film 4 is used for an electrode or a wiring, and bonded to the substrate 1.

To protect the metallic film 4 from peeling off, the intermediate product layer 3 is removed by a physical method such as an Ar sputtering method, as shown in FIG. 7C. Then, the metallic layer 4 is formed on the reaction layer 2a. The metallic layer 4 is made of gold (i.e., Au) or the like. The metallic layer 4 provides an electrode or a wiring, for example.

Thus, a surface metallization construction of the SiC semiconductor device 9 is completed. The surface metallization construction is formed from the reaction layer 2a and the metallic film 4.

In the above surface metallization method of the SiC substrate 1, the intermediate product layer 3 is removed by the physical method such as a sputtering method so that the ohmic contact characteristic is obtained. However, production of the intermediate product layer 3 is varied. Therefore, even when the physical method is performed to remove the intermediate product layer 3, it is difficult to remove the intermediate product layer 3 completely. Further, removal of the intermediate product layer 3 by means of the physical method may damage the reaction layer 2a. Thus, ohmic contact characteristic may be deteriorated, and the ohmic contact with the metallic film 4 as the electrode or the wiring may be deteriorated.

### SUMMARY OF THE INVENTION

In view of the above-described problem, it is an object of the present disclosure to provide a semiconductor device having a SiC substrate. It is another object of the present disclosure to provide a method for manufacturing a semiconductor device having a SiC substrate.

A semiconductor device includes: a SiC substrate; a silicide layer disposed on the SiC substrate; and a carbide layer disposed on the silicide layer. The silicide layer includes a first metal, and the carbide layer includes a second metal. The first metal is Ni or Ni alloy, and the second metal is Ti, Ta or W.

In the above device, the silicide layer provides excellent ohmic contact with the SiC substrate. The carbide layer functions as a stopper layer for preventing a carbon atom from diffusing and exposing on the surface of the substrate. Thus, a carbon related particle and a carbon particle do not exposed on the surface of the carbide layer. Accordingly, an electrode and a wiring to be formed on the carbide layer is prevented from peeling off from the carbide layer. Further, there is no need to remove the carbon related particle and the carbon particle from the surface of the carbide layer. Accordingly, the silicide layer and the carbide layer have no damage caused by removal step, so that the ohmic contact is sufficiently secured. Thus, the device has excellent ohmic contact and a high quality surface metallization construction having no damage.

A method for manufacturing a semiconductor device having a SiC substrate is provided. The method includes the steps of: forming a second metal film having a second metal on a surface of the SiC substrate; forming a first metal film having a first metal on the second metal film; and heating the SiC substrate with the second metal film and the first metal film thereon at a predetermined temperature equal to or higher than 600° C. The first metal is Ni or Ni alloy, and the second metal is Ti, Ta or W.

The above method provides the device having excellent ohmic contact. Further, an electrode and a wiring to be formed on the carbide layer is prevented from peeling off from the carbide layer. Furthermore, the silicide layer and the carbide layer have no damage caused by removal step, so that the ohmic contact is sufficiently secured. Thus, the device has excellent ohmic contact and a high quality surface metallization construction having no damage.

### BRIEF DESCRIPTION OF THE DRAWINGS

The above and other objects, features and advantages of the present invention will become more apparent from the following detailed description made with reference to the accompanying drawings. In the drawings:

FIG. 1 is a cross sectional view showing a semiconductor device according to a preferred embodiment;

FIGS. 2A to 2C are cross sectional views explaining a method for manufacturing the device according to the preferred embodiment;

FIG. 3 is a cross sectional view showing a semiconductor device according to a first modification of the preferred embodiment;

FIGS. 4A to 4C are cross sectional views showing semiconductor devices according to a second to fourth modifications of the preferred embodiment;

FIG. 5 is a cross sectional view showing a semiconductor device according to a fifth modification of the preferred embodiment;

FIG. 6A is a cross sectional view showing a semiconductor device according to a sixth modification of the preferred embodiment, and FIG. 6B is a graph showing a depth profile of the semiconductor device shown in FIG. 6A; and

FIGS. 7A to 7D are cross sectional views explaining a method for manufacturing a semiconductor device according to a comparison of the preferred embodiment.

### DETAILED DESCRIPTION OF THE PREFERRED EMBODIMENTS

A SiC semiconductor device having a SiC substrate according to a preferred embodiment is described. The device further includes a first metallic layer and a second metallic layer, which are disposed on the surface of the SiC substrate in this order. The first metallic layer is made of silicide including nickel (i.e., Ni) or nickel alloy. The second metallic layer is made of carbide including titanium (i.e., Ti), tantalum (i.e. Ta) or tungsten (i.e., W).

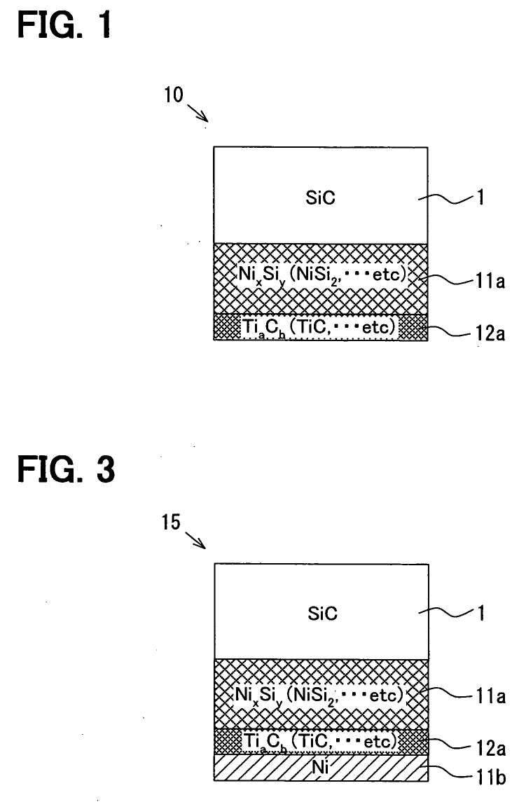

FIG. 1 shows an example of a semiconductor device according to the preferred embodiment. The semiconductor device 10 includes a SiC substrate 1. On the surface of the SiC substrate 1, a silicide layer 11a as the first metallic layer including nickel di-silicide (i.e., NiSi₂) or the like and a carbide layer 12a as the second metallic layer including titanium carbide (i.e., TiC) are formed in this order. The silicide layer 11a is made from NiₓSi_{y}. For example, the silicide layer 11a is a NiSi₂ layer. The carbide layer 12a is made from TiₐC_{b}. For example, the carbide layer 12a is a TiC layer. Thus, a metallization layer is made of the silicide layer 11a and the carbide layer 12a. The metallization layer is disposed on a backside of the SiC substrate 1 to mount the device 10 on a base member such as a heat sink and a lead frame.

The silicide layer 11a and the carbide layer 12a in the device 10 are formed in a high temperature heat treatment step in a manufacturing process of the device 10. The silicide layer 11a is made of reaction between nickel in the first metallic layer and silicon in the SiC substrate 1. The siliconde layer 11a, i.e., a NiSi₂ layer, provides ohmic contact characteristic with the SiC substrate 1. The carbide layer 12a is made of reaction between titanium in the second metallic layer and carbon in the SiC substrate 1. Here, the carbon in the SiC substrate 1 is a decomposition product of the SiC substrate 1. The carbide layer 12a functions as a stopper of carbon atom for preventing the carbon atom from diffusing on the surface of the device 10. Thus, a nickel carbide molecule and a carbon atom do not separate out on the surface of the device 10, i.e., on the surface of the carbide layer 12a. Accordingly, even after a metallic film is formed on the carbide layer 12a, the metallic film as an electrode or a wiring is not peeled off.

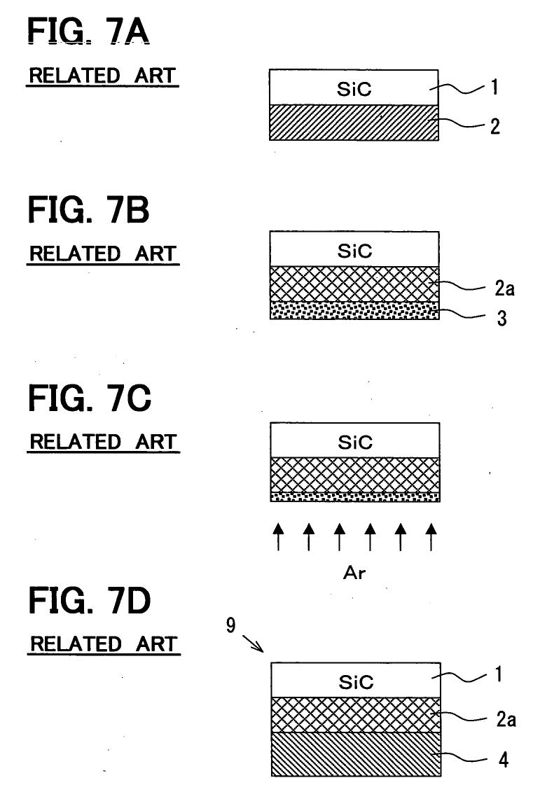

Further, in FIG. 7, the intermediate product layer 3 made from carbide and carbon is formed on the surface of the device 9 after high temperature heat treatment. However, the device 10 shown in FIG. 1 includes no intermediate product layer; and therefore, removal step of a physical removal method such as an Ar sputtering method is not needed. Accordingly, the silicide layer 11a and the carbide layer 12a are not damaged by the physical removal method, so that the ohmic contact characteristic of the device 10 is not reduced, i.e., deteriorated. Further, peeling off of the metallic film on the carbide layer 12a is limited. The surface metallization construction of the device 10 composed of the silicide layer 11a and the carbide layer 12a has excellent ohmic contact characteristic and small damage on the surface of the surface metallization construction.

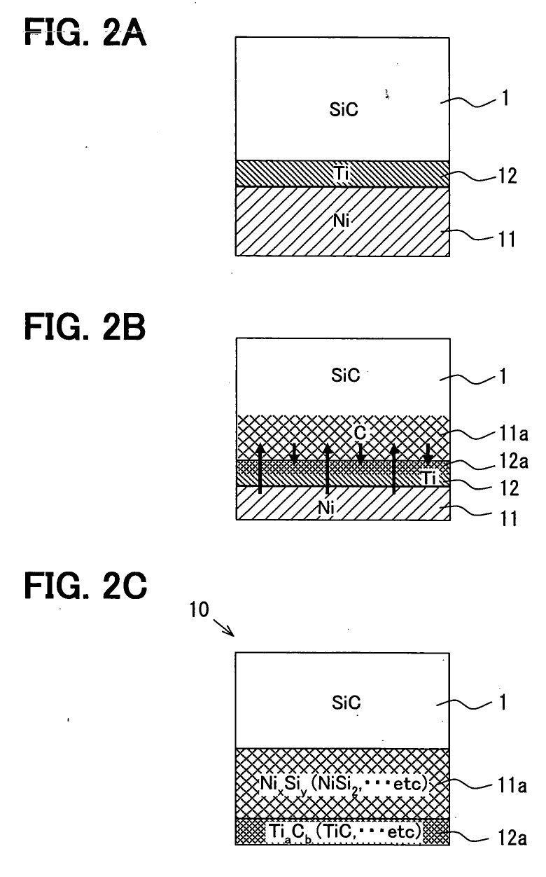

FIGS. 2A to 2C explain a method for manufacturing the device 10.

Firstly, as shown in FIG. 2A, a titanium film 12 as a second metallic film is formed on the surface of the SiC substrate 1. Then, a nickel film 11 as a first metallic film is formed on the Ti film 12. It is preferred that the thickness of the Ti film 12 is in a range between 5 nm and 50 nm. Further, it is preferred that the thickness of the Ni film 11 is in a range between 100 nm and 500 nm.

Then, the SiC substrate 1 with the Ti film 12 and the Ni film 11 is heated at a predetermined temperature equal to or higher than 600° C. in a high temperature heat treatment step.

FIG. 2B shows an intermediate state in the high temperature heat treatment step. FIG. 2C shows a final state in the high temperature heat treatment step.

As shown in FIG. 2B, in the heat treatment step, a nickel atom in the Ni film 11 penetrates through the Ti film 12 so that the nickel atom reaches and is diffused into the SiC substrate 1. Thus, the nickel atom reacts with silicon atom in the SiC substrate 1 so that the silicide layer 11a is formed. By using the silicide layer 11a, the SiC substrate 1 has excellent ohmic contact characteristic.

On the other hand, a carbon atom as a decomposition product in the SiC substrate is diffused into the Ti film 12. Then, the carbon atom reacts with a titanium atom in the Ti film 12 so that a carbide layer 12a is formed. Thus, by adjusting the thickness of the Ti film 12, the carbide layer 12a functions as a stopper for preventing the carbon atom from separating out on the surface of the device 10.

Preferably, the temperature of the heat treatment step is in a range between 900° C. and 1100° C. to secure the excellent ohmic contact characteristic. Further, it is preferred that the heat treatment step is performed in vacuum having a pressure equal to or lower than 1×10⁻⁸ Torr. In this case, an unwanted oxide film is not formed on the surface of the device 10. Here, the unwanted oxide film is attributes to oxygen adhered on the substrate 1 or an inner wall of a chamber. The chamber is used for the heat treatment step. Furthermore, it is preferred that a step of forming the Ni film 11 and the Ti film 12 and the heat treatment step are successively performed in the same chamber. Thus, the unwanted oxide film is prevented from forming on the surface of the device 10. Accordingly, bonding strength between the metallic film to be formed as the electrode or the wiring and the SiC substrate 1 is improved. Specifically, the bonding strength is prevented from reducing by the unwanted oxide film.

Although the first metallic film is made of Ni, alternatively, the first metallic film may be made of nickel alloy. Although the second metallic film is made of Ti, alternatively, the second metallic film may be made of Ta or W.

When the first metallic film is made of Ni or Ni alloy, the first metallic film reacts with the SiC substrate 1 in the heat treatment step so that the silicide layer 11a is formed. Thus, the ohmic contact with the SiC substrate 1 is secured. More preferably, the first metallic film is made of Ni in order to react easily with the SiC substrate 1.

When the second metallic film is made of Ti, Ta or W, the second metallic film reacts with the carbon atom as a decomposition product of the SiC substrate 1 in the heat treatment step so that the carbide layer 12a is formed. Thus, the carbide layer 12a functions as a stopper for preventing the carbon atom from separating out on the surface of the device 10. More preferably, the second metallic film is made of Ti in order to react easily with the carbon atom.

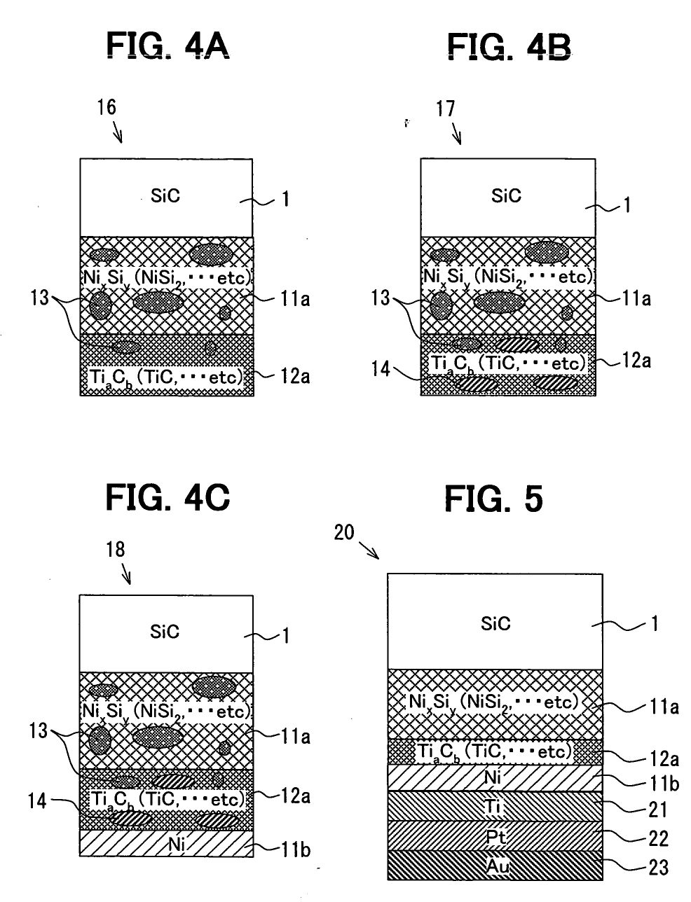

FIGS. 3 to 4C show other semiconductor devices 15-18 according to a first to a fourth modifications of the embodiment.

In the device 15 shown in FIG. 3, a third metallic layer 11b is formed on the carbide layer 12a. The third metallic layer 11b is made of the first metallic film, the second metallic film or an alloy film between the first metallic film and the second metallic film. Specifically, the third metallic layer 11b may be made of a Ni film, a Ti film or a Ni—Ti film.

The third metallic layer 11b is formed in such a manner that the thickness of the Ti film 12 and/or the thickness of the Ni film 11 are set to be thicker so that the Ni layer, the Ti layer or the Ni—Ti layer remains as the third metallic layer 11b after the heat treatment step. Thus, the third metallic layer 11b is formed without adding an additional new step. Thus, the manufacturing cost of the device 15 is almost the same as the device 10.

In the device 15, the carbon atom as the decomposition product of the SiC substrate 1 is prevented from separating out on the surface of the device 15. Accordingly, the metallic film on the device 15 is prevented from peeling off. Further, the carbide layer 12a and the silicide layer 11a are not damaged, and the ohmic contact characteristic is not deteriorated.

In the devices 16-18 shown in FIGS. 4A to 4C, a carbon particle or a graphite particle 13 as a decomposition product of the SiC substrate 1 is segregated (i.e., separated out) in the silicide layer 11a and/or the carbide layer 12a. Further, in the devices 17, 18, a Ni particle 14 made of Ni or Ni—Si alloy is segregated in the carbide layer 12a. The carbon particle 13 and the Ni particle 14 are formed to control the thickness of the Ti film 12, the thickness of the Ni film 11 and a condition of the heat treatment.

In the devices 16-18 shown in FIGS. 4A to 4C, when the carbon particle 13 and/or the Ni particle 14 are not disposed, i.e., exposed on the surface of the carbide layer 12a and/or the surface of the third metallic layer 11b, the metallic film to be formed on the surface of the carbide layer 12 or the surface of the third metallic layer 11b is prevented from peeling off. Further, no step for removing the intermediate product layer is needed, so that the silicide layer 11a and the carbide layer 12a are not damaged. Accordingly, the ohmic contact characteristic of the devices 16-18 is not deteriorated.

FIG. 5 shows another semiconductor device 20 according to a fifth modification of the embodiment. The device 20 includes a buffer layer 21, a barrier layer 22 and a fourth metallic layer 23, which are formed on the third metallic layer 11b in this order. The third metallic layer 11b is made of Ni, the buffer layer 21 is made of Ti, the barrier layer 22 is made of Pt (i.e., platinum), and the fourth metallic layer 23 is made of gold (i.e., Au).

Alternatively, the buffer layer 21 may be made of chrome (i.e., Cr). The buffer layer 21 is formed between the carbide layer 12a or the third metallic layer 11b and the barrier layer 22 so that adhesiveness between the carbide layer 12a or the third metallic layer 11b and the barrier layer 22 is improved. Here, the device 20 may have no buffer layer 21 when a combination of materials of the carbide layer 12a, the third metallic layer 11b and the barrier layer 22 is appropriately determined.

The barrier layer 22 may be made of W or Ti—W alloy. The barrier layer 22 is formed on the carbide layer 12a, the third metallic layer 11b or the buffer layer 21. The barrier layer 22 does not melt at a temperature in a range between 150° C. and 500° C., which is a soldering temperature in a post-process. Thus, when the device is mounted on a base member, a solder member is not diffused into the SiC substrate 1.

The fourth metallic layer 23 may be made of gold alloy. The fourth metallic layer 23 is formed on the barrier layer 22. The fourth metallic layer 23 and/or the barrier layer 22 have low resistance and high heat resistance. Further, the fourth metallic layer 23 is suitable to bond with a gold-based solder. Accordingly, the fourth metallic layer 23 and/or the barrier layer 22 maintain high heat resistance of the SiC substrate 1. Thus, the fourth metallic layer 23 and/or the barrier layer 22 are suitable for the electrode and the wiring.

Preferably, the thickness of the barrier layer 22 is in a range between 20 nm and 100 nm. Thus, the Ni atom or Ni alloy in the first metallic film, the gold atom or gold alloy in the fourth metallic layer 23, and/or the solder member to be used in the post-process are prevented from being diffused each other.

In the device 20, it is preferred that the buffer layer 21 and the barrier layer 22 are formed by a sputtering method. Thus, the buffer layer 21 and/or the barrier layer 22 have high adhesiveness.

Before forming the buffer layer 21 and/or the barrier layer 22, it is preferred that the surface of the carbide layer 12a or the third metallic layer 11b is processed by argon plasma. Here, the surface of the carbide layer 12a or the third metallic layer 11b is a heat treatment layer of the second metallic film 12 and the first metallic film 11. Thus, the adhesiveness of the buffer layer 21 and/or the barrier layer 22 on the heat treatment layer (i.e., the carbide layer 12a or the third metallic layer 11b) is improved.

In a process for manufacturing the device 20, it is preferred that a step of forming the buffer layer 21 and/or a step of forming the barrier layer 22 and a step of forming the fourth metallic layer 23 are continuously performed in the same chamber. Further, it is preferred that the step of forming the buffer layer 21 and/or the step of forming the barrier layer 22 and the step of forming the fourth metallic layer 23 are performed in vacuum having a pressure equal to or lower than 1×10⁻⁸ Torr. Thus, unwanted oxygen is not introduced into the substrate 1, so that the adhesiveness of each layer is prevented from reducing.

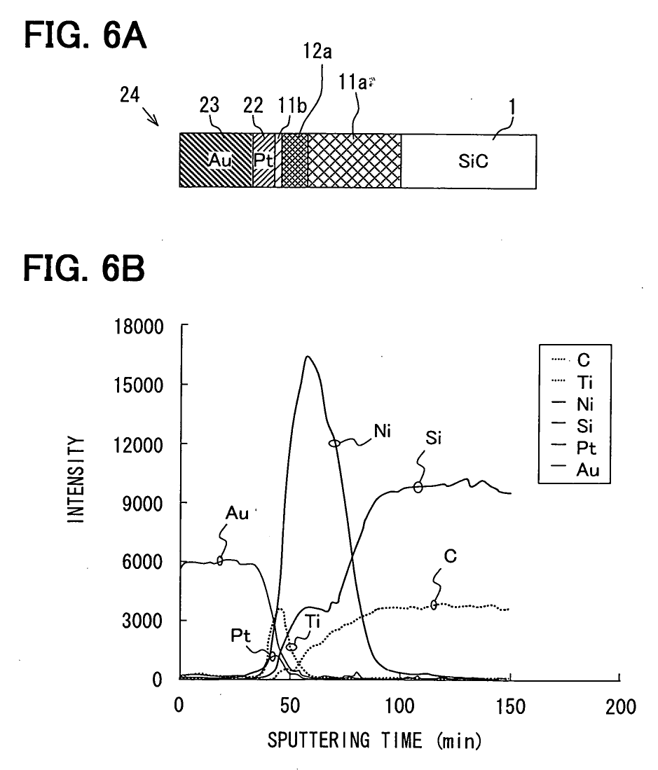

FIG. 6A shows another semiconductor device 24 according to a sixth modification of the embodiment. FIG. 6B shows a depth profile of each element in the device 24 by using an Auger electron spectroscopy analysis with sputtering the surface of the device 24.

A horizontal axis of FIG. 6B shows a sputtering time corresponding to a depth from the surface of the device 24. The device 24 shown in FIG. 6A has no buffer layer 21 made of Ti. Here, in the device 24, the carbon particle 13 and/or the Ni particle 14 are segregated in the silicide layer 11a and/or the carbide layer 12a. However, the carbide particle 13 and/or the Ni particle 14 are not shown in FIG. 6A.

The devices 20, 24 shown in FIGS. 5 and 6 can be soldered with a base member through a gold-based solder. Specifically, the fourth metallic layer 23 of the devices 20, 24 is bonded to the base member. The gold-based solder is made of, for example, Au—Ge or Au—Sn. Thus, the high heat resistance of the devices 20, 24 is secured, so that the devices 20, 24 can be operated at a comparatively high temperature in a range between 150° C. and 250° C. Further, high reliability of the devices 20, 24 is secured. Accordingly, when the device 20, 24 is mounted on a base member such as a heat sink and a lead frame, the fourth metallic layer 23 disposed on the backside of the SiC substrate 1 is suitable for soldering through the gold-based solder.

In the devise 20, 24, the fourth metallic layer 23 may be press-bonded to the base member through the gold-based solder. In this case, gold material in the fourth metallic layer 23 is press-bonded to gold material in the gold-based solder. In this case, the device 20, 24 maintains high heat resistance, so that the device 20, 24 can be operated at comparatively high temperature equal to or higher than 250° C.

The present disclosure has the following aspects.

According to a first aspect of the present disclosure, a semiconductor device includes: a SiC substrate; a silicide layer disposed on the SiC substrate; and a carbide layer disposed on the silicide layer. The silicide layer includes a first metal, and the carbide layer includes a second metal. The first metal is Ni or Ni alloy, and the second metal is Ti, Ta or W.

In the above device, the silicide layer provides excellent ohmic contact with the SiC substrate. The carbide layer functions as a stopper layer for preventing a carbon atom from diffusing and exposing on the surface of the substrate. Thus, a carbon related particle and a carbon particle do not exposed on the surface of the carbide layer. Accordingly, an electrode and a wiring to be formed on the carbide layer is prevented from peeling off from the carbide layer. Further, there is no need to remove the carbon related particle and the carbon particle from the surface of the carbide layer. Accordingly, the silicide layer and the carbide layer have no damage caused by removal step, so that the ohmic contact is sufficiently secured. Thus, the device has excellent ohmic contact and a high quality surface metallization construction having no damage.

Alternatively, the device may further include a first particle made of carbon or graphite. The first particle is disposed in the silicide layer or the carbide layer. In this case, since the first particle is not exposed on the surface of the carbide layer, the device has excellent ohmic contact and a high quality surface metallization construction having no damage.

Alternatively, the device may further include a second particle made of the first metal or alloy between the first metal and silicon in the SiC substrate. The second particle is disposed in the carbide layer. In this case, since the second particle is not exposed on the surface of the carbide layer, the device has excellent ohmic contact and a high quality surface metallization construction having no damage.

Alternatively, the device may further include a third metallic layer disposed on the carbide layer. The third metallic layer is made of the first metal, the second metal or alloy between the first metal and the second metal.

Alternatively, the device may further include a barrier layer disposed on the third metallic layer; and a fourth metallic layer disposed on the barrier layer. The barrier layer is made of Pt, W or Ti—W alloy, and the fourth metallic layer is made of gold or gold alloy. In this case, the barrier layer does not melt at a soldering temperature in a range between 150° C. and 500° C. Accordingly, the barrier layer protects the solder member from diffusing. Further, the fourth metallic layer has low resistance and high heat resistance. Furthermore, the fourth metallic layer is suitably used for soldering with a gold-based solder member. Accordingly, the fourth metallic layer does not deteriorate high temperature performance of the SiC device; and therefore, the fourth metallic layer is suitably sued for a metallic pad of an electrode or a wiring.

Alternatively, the device may further include a barrier layer disposed on the carbide layer; and a fourth metallic layer disposed on the barrier layer. The barrier layer is made of Pt, W, Ti—W alloy, and the fourth metallic layer is made of gold or gold alloy.

Alternatively, the barrier layer may have a thickness in a range between 20 nm and 100 nm. In this case, the first metal in the silicide layer, gold in the fourth metallic layer and/or a solder member used in a post-process are prevented from diffusing mutually.

Alternatively, the device may further include a buffer layer disposed between the carbide layer and the barrier layer. The buffer layer is made of Ti or Cr. In this case, the buffer layer provides higher adhesiveness among the carbide layer, the third metallic layer and/or the barrier layer.

Alternatively, the fourth layer may be capable of soldering on a base member with a gold-based solder member. In this case, the device can operate at high temperature in a range between 150° C. and 250° C. Further, the reliability of the device is improved. Accordingly, the device is suitably used for bonding between the device and a base member such as a heat sink and a lead frame with a gold-based solder member.

Alternatively, the fourth metallic layer may be capable of press-bonding on a base member with a gold-based solder member so that gold in the fourth metallic layer and gold in the gold-based solder member are press-bonded.

According to a second aspect of the present disclosure, a method for manufacturing a semiconductor device having a SiC substrate is provided. The method includes the steps of: forming a second metal film having a second metal on a surface of the SiC substrate; forming a first metal film having a first metal on the second metal film; and heating the SiC substrate with the second metal film and the first metal film thereon at a predetermined temperature equal to or higher than 600° C. The first metal is Ni or Ni alloy, and the second metal is Ti, Ta or W.

The above method provides the device having excellent ohmic contact. Further, an electrode and a wiring to be formed on the carbide layer is prevented from peeling off from the carbide layer. Furthermore, the silicide layer and the carbide layer have no damage caused by removal step, so that the ohmic contact is sufficiently secured. Thus, the device has excellent ohmic contact and a high quality surface metallization construction having no damage.

Alternatively, the second metal film may have a thickness in a range between 5 nm and 50 nm, and the first metal film may have a thickness in a range between 100 nm and 5.00 nm.

Alternatively, the predetermined temperature in the step of heating may be in a range between 900° C. and 1100° C.

Alternatively, the step of heating may be performed under a pressure equal to or lower than 1×10⁻⁸ Torr.

Alternatively, the step of forming the second metal film, the step of forming the first metal film, and the step of heating may be performed continuously in a same chamber.

Alternatively, the method may further include the steps of: forming a barrier layer on a heat treatment layer, which is formed from the second metal film and the first metal film after the step of heating; and forming a fourth metallic layer on the barrier layer. The barrier layer is made of Pt, W or Ti—W alloy, and the fourth metallic layer is made of Au or Au alloy.

Alternatively, the method may further include the step of: forming a buffer layer between the heat treatment layer and the barrier layer. The buffer layer is made of Ti or Cr.

Alternatively, at least one of the step of forming the buffer layer and the step of forming the barrier layer may be performed by a sputtering method.

Alternatively, the method may further include the step of: performing surface-treatment on a surface of the heat treatment layer with using Ar plasma before the step of forming the buffer layer and the step of forming the barrier layer.

Alternatively, the step of forming the buffer layer, the step of forming the barrier layer, and the step of forming the fourth metallic layer may be performed continuously in a same chamber.

Alternatively, the step of forming the buffer layer, the step of forming the barrier layer, and the step of forming the fourth metallic layer may be performed under a pressure equal to or lower than 1×10⁻⁸ Torr.

Alternatively, the method may further include the step of: soldering the fourth metallic layer on a base member with a gold-based solder member.

Alternatively, in the step of soldering, the fourth metallic layer may be press-bonded on the base member with the gold-based solder member so that gold in the fourth metallic layer and gold in the gold-based solder member are press-bonded.

While the invention has been described with reference to preferred embodiments thereof, it is to be understood that the invention is not limited to the preferred embodiments and constructions. The invention is intended to cover various modification and equivalent arrangements. In addition, while the various combinations and configurations, which are preferred, other combinations and configurations, including more, less or only a single element, are also within the spirit and scope of the invention.

What is claimed is:

1. A semiconductor device comprising:
a SiC substrate;
a silicide layer disposed on the SiC substrate; and
a carbide layer disposed on the silicide layer, wherein
the silicide layer includes a first metal, and the carbide layer includes a second metal,
the first metal is Ni or Ni alloy, and
the second metal is Ti, Ta or W.

2. The device according to claim 1, wherein
the first metal is Ni, and
the second metal is Ti.

3. The device according to claim 1, further comprising:
a first particle made of carbon or graphite, wherein
the first particle is disposed in the silicide layer or the carbide layer.

4. The device according to claim 1, further comprising:
a second particle made of the first metal or alloy between the first metal and silicon in the SiC substrate, wherein
the second particle is disposed in the carbide layer.

5. The device according to claim 1, further comprising:
a third metallic layer disposed on the carbide layer, wherein
the third metallic layer is made of the first metal, the second metal or alloy between the first metal and the second metal.

6. The device according to claim 5, further comprising:
a barrier layer disposed on the third metallic layer; and
a fourth metallic layer disposed on the barrier layer, wherein
the barrier layer is made of Pt, W or Ti—W alloy, and
the fourth metallic layer is made of gold or gold alloy.

7. The device according to claim 1, further comprising:
a barrier layer disposed on the carbide layer; and
a fourth metallic layer disposed on the barrier layer, wherein
the barrier layer is made of Pt, W, Ti—W alloy, and
the fourth metallic layer is made of gold or gold alloy.

8. The device according to claim 7, wherein
the barrier layer has a thickness in a range between 20 nm and 100 nm.

9. The device according to claim 7, further comprising:
a buffer layer disposed between the carbide layer and the barrier layer, wherein
the buffer layer is made of Ti or Cr.

10. The device according to claim 7, wherein
the fourth layer is capable of soldering on a base member with a gold-based solder member.

11. The device according to claim 7, wherein
the fourth metallic layer is capable of press-bonding on a base member with a gold-based solder member so that gold in the fourth metallic layer and gold in the gold-based solder member are press-bonded.

12. A method for manufacturing a semiconductor device having a SiC substrate, the method comprising the steps of:
forming a second metal film having a second metal on a surface of the SiC substrate;
forming a first metal film having a first metal on the second metal film; and
heating the SiC substrate with the second metal film and the first metal film thereon at a predetermined temperature equal to or higher than 600° C., wherein
the first metal is Ni or Ni alloy, and
the second metal is Ti, Ta or W.

13. The method according to claim 12, wherein
the first metal is Ni, and
the second metal is Ti.

14. The method according to claim 12, wherein
the second metal film has a thickness in a range between 5 nm and 50 nm, and
the first metal film has a thickness in a range between 100 nm and 500 nm.

15. The method according to claim 12, wherein
the predetermined temperature in the step of heating is in a range between 900° C. and 1100° C.

16. The method according to claim 12, wherein
the step of heating is performed under a pressure equal to or lower than 1×10⁻⁸ Torr.

17. The method according to claim 12, wherein
the step of forming the second metal film, the step of forming the first metal film, and the step of heating are performed continuously in a same chamber.

18. The method according to claim 12, further comprising the steps of:
forming a barrier layer on a heat treatment layer, which is formed from the second metal film and the first metal film after the step of heating; and
forming a fourth metallic layer on the barrier layer, wherein
the barrier layer is made of Pt, W or Ti—W alloy, and
the fourth metallic layer is made of Au or Au alloy.

19. The method according to claim 18, further comprising the step of:
forming a buffer layer between the heat treatment layer and the barrier layer, wherein
the buffer layer is made of Ti or Cr.

20. The method according to claim 19, wherein
at least one of the step of forming the buffer layer and the step of forming the barrier layer are performed by a sputtering method.

21. The method according to claim 20, further comprising the step of:
performing surface-treatment on a surface of the heat treatment layer with using Ar plasma before the step of forming the buffer layer and the step of forming the barrier layer.

22. The method according to claim 19, wherein
the step of forming the buffer layer, the step of forming the barrier layer, and the step of forming the fourth metallic layer are performed continuously in a same chamber.

23. The method according to claim 19, wherein
the step of forming the buffer layer, the step of forming the barrier layer, and the step of forming the fourth metallic layer are performed under a pressure equal to or lower than 1×10⁻⁸ Torr.

24. The method according to claim 18, further comprising the step of:
soldering the fourth metallic layer on a base member with a gold-based solder member.

25. The method according to claim 24, wherein
in the step of soldering, the fourth metallic layer is press-bonded on the base member with the gold-based solder member so that gold in the fourth metallic layer and gold in the gold-based solder member are press-bonded.
